(19) United States
(12) Patent Application Publication
(10) Pub. No.: US 2025/0072105 A1
(43) Pub. Date: Feb. 27, 2025

(54) VERTICAL STRUCTURE-BASED FIELD EFFECT TRANSISTOR (FET) INPUT/OUTPUT DEVICE INTEGRATION

(71) Applicant: QUALCOMM Incorporated, San Diego, CA (US)

(72) Inventors: Xia LI, San Diego, CA (US); Junjing BAO, San Diego, CA (US); Biswa Ranjan PANDA, Bengaluru (IN); Ramesh MANCHANA, Hyderabad (IN)

(21) Appl. No.: 18/455,511

(22) Filed: Aug. 24, 2023

(51) Int. Cl. H01L 27/092; H01L 21/8238; H01L 29/06; H01L 29/417; H01L 29/423; H01L 29/775

(52) U.S. Cl. CPC H01L 27/092; H01L 21/823857; H01L 29/0673; H01L 29/41775; H01L 29/42392; H01L 29/775

(57) ABSTRACT

An integrated circuit (IC) device includes an N-type field effect transistor (FET). The N-type FET includes an N-type vertical structure on a substrate, including an N-type gate region having a first normal-k oxide layer on a semiconductor layer of the N-type vertical structure, an N-type work-function metal (WFM) layer on the first normal-k oxide layer and sidewall spacers of the N-type gate region, and a first metal gate on the N-type WFM layer. The IC device includes a first P-type FET. The first P-type FET includes a first P-type vertical structure on the substrate, including a first P-type gate region having a second normal-k oxide layer on a first semiconductor layer of the first P-type vertical structure, a first P-type WFM layer on the second normal-k oxide layer and sidewall spacers of the first P-type gate region, and a second metal gate on the first P-type WFM layer.

### BACKGROUND

### Field

Aspects of the present disclosure relate to semiconductor devices and, more particularly, to a vertical structure-based field effect transistor (FET) input/output device integration.

### Background

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing.

Although existing methods of fabricating IC devices are adequate for their intended purposes, they are not entirely satisfactory in all respects. For example, fin-based devices are three-dimensional structures on the surface of a semiconductor substrate. A fin-based or nanosheet field effect transistor (FET) may be referred to as a FinFET or GAA. One advancement implemented as technology nodes shrink, in some IC designs, is the replacement of the polysilicon gate electrode with a metal gate electrode to improve device performance with the decreased feature sizes.

Replacement metal gate (RMG) technology replaces conventional polysilicon gates with a high-k (HK) metal gate (HKMG) to avoid high-k dielectric crystallization incurred by conventional polysilicon gates during a thermal process. Unfortunately, a thickness of an HKMG film specified for nanosheet-based GAA FET input/output (IO) devices may limit the space available for depositing a work function metal (WFM), which may be used to modulate a threshold voltage (Vₜ) of the nanosheet-based GAA FET IO device. A nanosheet-based GAA FET IO device having a metal gate and sufficient space for depositing a WFM is desired.

### SUMMARY

An integrated circuit (IC) device includes an N-type field effect transistor (FET). The N-type FET includes an N-type vertical structure on a substrate, including an N-type gate region having a first normal-k oxide layer on a semiconductor layer of the N-type vertical structure, an N-type work-function metal (WFM) layer on the first normal-k oxide layer and sidewall spacers of the N-type gate region, and a first metal gate on the N-type WFM layer. The IC device includes a first P-type FET. The first P-type FET includes a first P-type vertical structure on the substrate, including a first P-type gate region having a second normal-k oxide layer on a first semiconductor layer of the first P-type vertical structure, a first P-type WFM layer on the second normal-k oxide layer and sidewall spacers of the first P-type gate region, and a second metal gate on the first P-type WFM layer.

A method for fabricating an integrated circuit device is described. The method includes forming an N-type vertical structure on a substrate and including an N-type gate region and a first P-type vertical structure on the substrate and including a first P-type gate region. The method also includes growing a first normal-k oxide layer on a first semiconductor layer of the N-type vertical structure, and a second normal-k oxide layer on a second semiconductor layer of the first P-type vertical structure. The method further includes depositing an N-type work-function metal (WFM) layer on the first normal-k oxide layer and sidewall spacers of the N-type gate region. The method also includes depositing a first P-type WFM layer on the second normal-k oxide layer and sidewall spacers of the first P-type gate region. The method further includes forming a first metal gate on the N-type WFM layer and a second metal gate on the first P-type WFM layer to from an N-type field effect transistor (FET) and a first P-type FET.

This has outlined, broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for conducting the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer.

FIG. 2 illustrates a cross-sectional view of the die of FIG. 1.

FIG. 3 illustrates a cross-sectional view of a metal oxide semiconductor field effect transistor (MOSFET) device.

FIG. 4 illustrates a fin-based field effect transistor (FinFET), having a low-k oxide in a gate region, according to various aspects of the present disclosure.

FIG. 5 illustrates a gate all around (GAA) field effect transistor (FET), having a low-k oxide in a gate region, according to various aspects of the present disclosure.

FIG. 6 is a schematic diagram illustrating an integrated circuit (IC) device including gate all around (GAA) field effect transistors (FETs) having a normal-k oxide in gate regions according to an input/output (IO) GAA FET configuration, according to various aspects of the present disclosure.

FIGS. 7A-7L are schematic diagrams illustrating a process for forming the integrated circuit (IC) device of FIG. 6, according to an input/output (IO) gate all around (GAA) field effect transistor (FET) configuration, according to various aspects of the present disclosure.

FIG. 8 is a process flow diagram illustrating a method for fabricating an integrated circuit (IC) device in an input/output (IO) gate all around (GAA) field effect transistor (FET) configuration, according to various aspects of the present disclosure.

FIG. 9 is a block diagram showing an exemplary wireless communications system in which an aspect of the disclosure may be advantageously employed.

FIG. 10 is a block diagram illustrating a design workstation used for circuit, layout, and logic design of a transistor structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down has also increased the complexity of processing and manufacturing ICs. Realizing these advancements involves similar developments in IC processing and manufacturing.

Fin-based devices represent a significant advance in IC technology over planar-based devices. Fin-based devices are three-dimensional structures on the surface of a semiconductor substrate. A fin field effect transistor (FinFET) is a fin-based metal oxide semiconductor field effect transistor (MOSFET). A nanowire field effect transistor (FET) also represents a significant advance in IC technology. A gate-all-around (GAA) nanosheet-based device is another three-dimensional structure on the surface of a semiconductor substrate. Other fin-based devices include omega-gate devices as well as pi-gate devices. A vertical structure-based field effect transistor may be referred to as a FinFET device, a GAA nanosheet-based device, a GAA nanowire-based device, or other like FET device.

One advancement implemented as technology nodes shrink, in some IC designs, is the replacement of the polysilicon gate electrode with a metal gate electrode to improve device performance with the decreased feature sizes. Although existing methods of fabricating IC devices are adequate for their intended purposes, the methods are not entirely satisfactory in all respects. For example, the vertical structure-based devices may be implemented using replacement metal gate (RMG) technology.

Replacement metal gate (RMG) technology replaces conventional polysilicon gates with a high-k (HK) metal gate (HKMG) to avoid HK dielectric crystallization incurred by conventional polysilicon gates during a thermal process. Unfortunately, a thickness of an HKMG film specified for vertical structure-based GAA FET input/output (IO) devices may limit the space available for depositing a work function metal (WFM) layer, which may be used to modulate a threshold voltage (Vₜ) of the vertical structure-based GAA FET IO device. A vertical structure-based GAA FET IO device having a metal gate and sufficient space for depositing a WFM layer is desired.

Various aspects of the present disclosure are directed to vertical structure-based field effect GAA transistor (FET) IO devices having a normal-k oxide (e.g., k˜3.9) in a gate region. The process flow for fabricating the fin-based FET IO devices having a normal-k oxide in a gate region may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably unless such interchanging would tax credulity.

According to aspects of the present disclosure, an IO device having vertical structure-based GAA field effect transistors (FETs) having a normal-k oxide in a gate region is described. The GAA IO device includes an N-type FET having an N-type vertical structure on a substrate. The N-type GAA IO FET includes an N-type gate region having a first normal-k oxide layer on a first semiconductor layer of the N-type vertical structure. Additionally, the N-type FET includes an N-type work-function metal (WFM) layer on the first normal-k oxide layer and sidewall spacers of the gate region, as well as a first metal gate on the N-type WFM layer. The GAA IO device further includes a first P-type FET, having a first P-type vertical structure on the substrate. The P-type GAA FET includes a first P-type gate region having a second normal-k oxide layer on a second semiconductor layer of the P-type vertical structure. Additionally, the P-type FET includes a first P-type WFM layer on the second normal-k oxide layer and sidewall spacers of the first P-type gate region, as well as a second metal gate on the first P-type WFM layer.

In various aspects of the present disclosure, the GAA IO device further includes an input/output (IO) pad coupled to a source/drain region of the N-type GAA FET and a drain/source region of the P-type GAA FET. Additionally, the GAA IO device includes a second P-type GAA FET. In various aspects of the present disclosure, the second P-type GAA FET is a core P-FET device, composed of a second P-type vertical structure on the substrate and including a second P-type gate region having a high-k gate oxide. In some aspects of the present disclosure, the high-k gate oxide is on a second semiconductor layer of the second P-type vertical structure and sidewall spacers of the second P-type gate region. Additionally, the second P-type FET includes a third metal gate on the second P-type WFM layer.

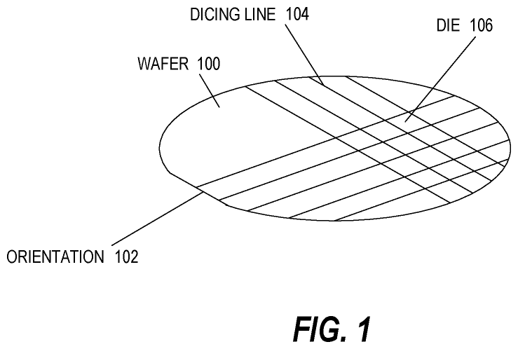

FIG. 1 illustrates a perspective view of a semiconductor wafer, which may be used for fabricating a vertical structure-based GAA field effect transistor (FET) having a normal-k oxide in a gate region, according to aspects of the present disclosure. A wafer 100 may be a semiconductor wafer or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a single material (e.g., silicon (Si), germanium (Ge)) or a compound material, such as gallium arsenide (GaAs), gallium nitride (GaN), or indium phosphide (InP), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, diverse types of electronic devices may be formed in or on the wafer 100.

The wafer 100 has an orientation 102 that indicates the crystalline orientation of the wafer 100. The orientation 102 may be a flat edge of the wafer 100 as shown in FIG. 1 or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and [symbol] , which are the Miller indices for a plane (hk [symbol] ) in the crystal. Each index denotes a plane orthogonal to a direction (h, k, [symbol] ) on the basis of the reciprocal lattice vectors. The integers are usually written in lowest terms (e.g., their greatest common divisor should be 1). Miller index 100 represents a plane orthogonal to direction h; index 010represents a plane orthogonal to direction k, and index 001 represents a plane orthogonal to [symbol] . For some crystals, negative numbers are used (written as a bar over the index number) and for some crystals, such as gallium nitride, more than three numbers may be employed to describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

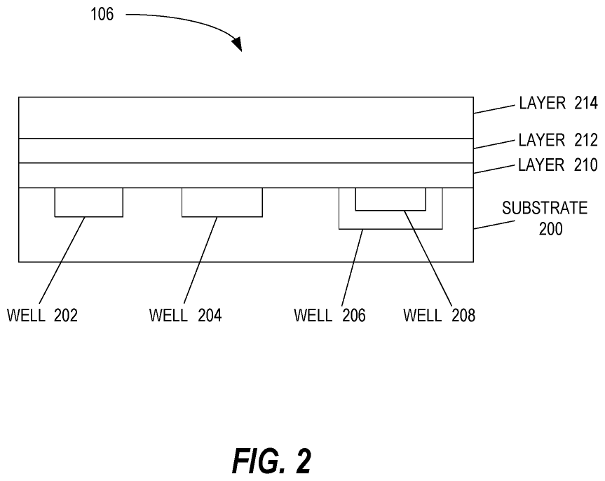

FIG. 2 illustrates a cross-sectional view of the die 106 of FIG. 1, which may be used for fabricating a vertical structure-based field effect transistor (FET) having a high-k oxide in a gate region, according to aspects of the present disclosure. In the die 106, there may be a substrate 200, which may be a semiconductor material and/or may function as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within the substrate 200 (e.g., a semiconductor substrate), there may be wells 202 and 204 of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

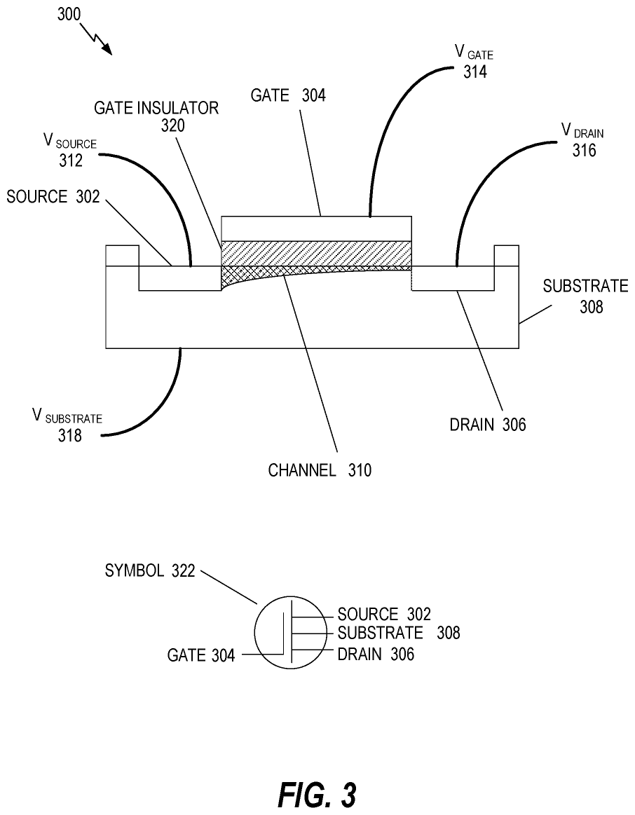

FIG. 3 illustrates a cross-sectional view of a metal oxide semiconductor field effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308 or may be fabricated as areas above the substrate 308, or as part of other layers on the die 106. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For P-type MOSFETs (using holes as charge carriers in the channel 310), an arrow is applied to the substrate 308 terminal in the symbol 322 pointing toward the gate 304 terminal.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304, as described below.

To interconnect to the MOSFET device 300, or to interconnect to other devices in the die 106 (e.g., semiconductor), interconnect traces or layers are used. These interconnect traces may be in one or more layers (e.g., 210-214), or may be in other layers of the die 106.

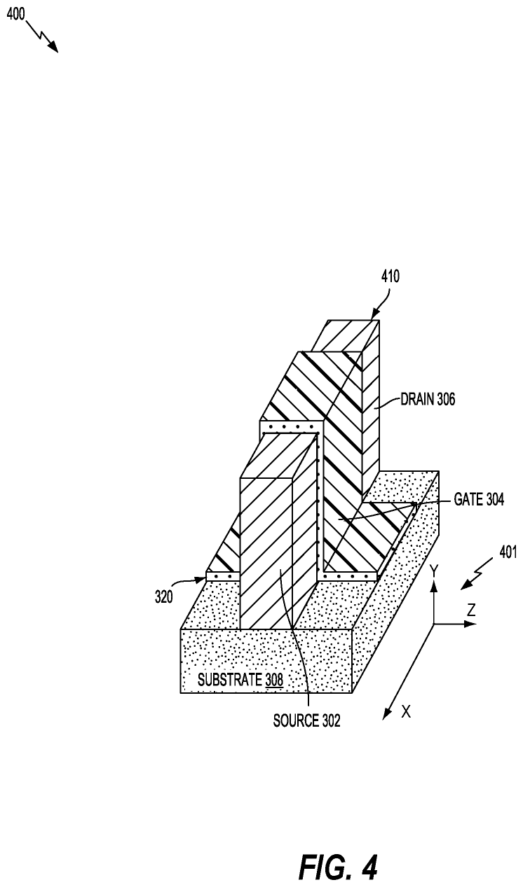

FIG. 4 illustrates a fin-based field effect transistor (FinFET), having a high-k oxide in a gate region, according to various aspects of the present disclosure. As shown in FIG. 4, a FinFET 400 operates in a similar fashion to the MOSFET device 300 described with respect to FIG. 3. A fin 410 of the FinFET 400, however, is grown or otherwise coupled to the substrate 308 of FIG. 3. The substrate 308 may be a semiconductor substrate or other like supporting layer, for example, comprised of an oxide layer, a nitride layer, a metal oxide layer, or a silicon layer. The fin 410 includes the source 302 and the drain 306. A gate 304 is disposed on the fin 410 and on the substrate 308 through a gate insulator 320. An XYZ axis 401 of the FinFET 400 is also shown.

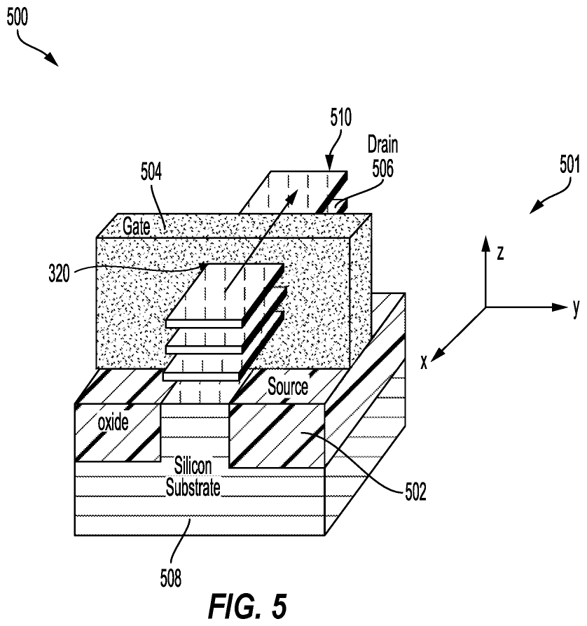

FIG. 5 illustrates a gate all around (GAA) field effect transistor (FET), having a high-k oxide in a gate region, according to aspects of the present disclosure.

As shown in FIG. 5, a nanosheet 510 of the GAA FET 500 is grown or otherwise coupled to a substrate 508. The substrate 508 may be a semiconductor substrate or other like supporting layer, for example, comprised of an oxide layer, a nitride layer, a metal oxide layer, or a silicon layer. The nanosheet 510 also includes a source 502 and a drain 506. Additionally, a gate 504 is disposed on and surrounds the nanosheet 460 on four sides through a gate insulator 320 to provide first and second channels. The gate 504 is also on the substrate 508. An XYZ axis 501 of the GAA FET 500 is also shown. As illustrated by the XYZ axis 501, the Y and Z axis are swapped in the configuration of the GAA FET 500 relative to the XYZ axis 401 of the FinFET 400 in FIG. 4.

FIGS. 4 and 5 illustrate vertical structure-based field effect transistors (FETs). The vertical structure of the FinFET 400 and the GAA FET 500 facilitates a physical size of the FinFET 400 and the GAA FET 500 that is smaller than the MOSFET device 300 structure shown in FIG. 3. This reduction in the physical size allows for more devices per unit area on the die 106 shown in FIG. 1. The FinFET 400 and the GAA FET 500 may be fabricated through processes including a front-end-of-line (FEOL), a middle-of-line (MOL) and a back-end-of-line (BEOL). An MOL process includes gate and terminal contact formation, which may be referred to as a zero interconnect (MO) layer. An MOL layer trench contacts the source and drain regions of the FinFET 400 and the GAA FET 500 are referred to as metal to diffusion (MD) contacts, including metal to diffusion vias (VD) and gate vias (VG).

Vertical structure-based devices, such as the FinFET 400 and the GAA FET 500, represent a significant advance in integrated circuit (IC) technology over planar-based devices. Vertical structure-based devices are three-dimensional structures on the surface of a semiconductor substrate. A FinFET transistor (e.g., FinFET 400) is a fin-based metal oxide semiconductor field effect transistor (MOSFET). A nanowire FET also represents a significant advance in IC technology. A gate all around (GAA) nanosheet-based device (e.g., GAA FET 500) is another three-dimensional structure on the surface of a semiconductor substrate. Other vertical structure-based devices include omega-gate devices as well as pi-gate devices. A vertical structure-based field effect transistor may be referred to as a FinFET device, a GAA nanosheet-based device, a GAA nanowire-based device, an omega-gate device, a pi-gate device, or other like FET device.

One advancement implemented as technology nodes shrink, in some IC designs, is the replacement of the polysilicon gate electrode with a metal gate electrode to improve device performance with the decreased feature sizes. Although existing methods of fabricating IC devices are adequate for their intended purposes, they are not entirely satisfactory in all respects. For example, the vertical structure-based devices may be implemented using replacement metal gate (RMG) technology.

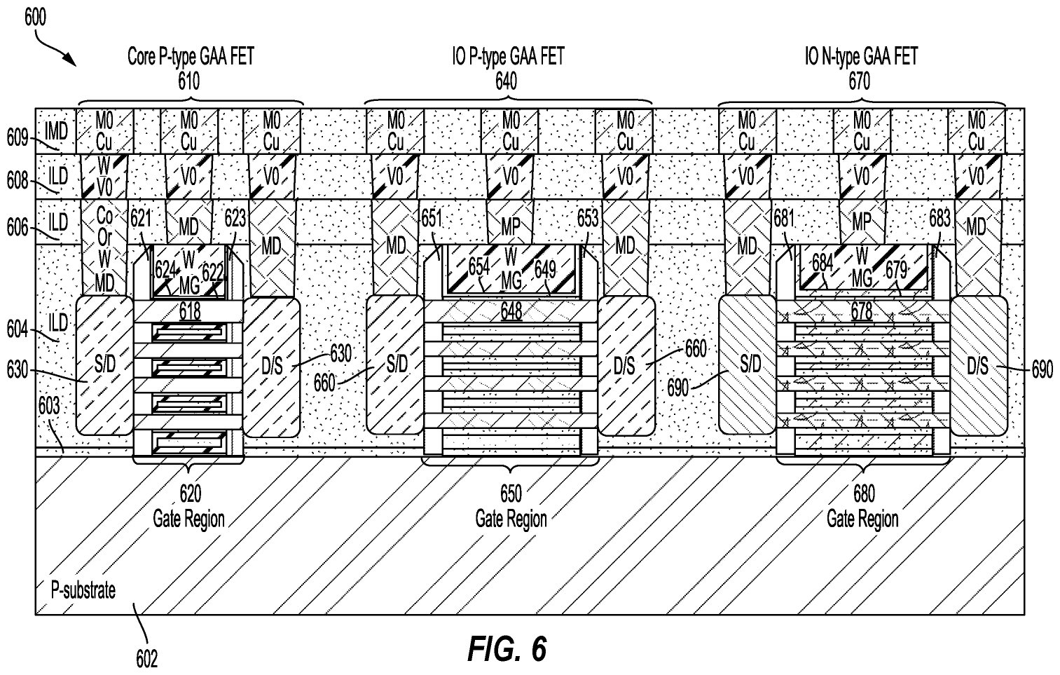

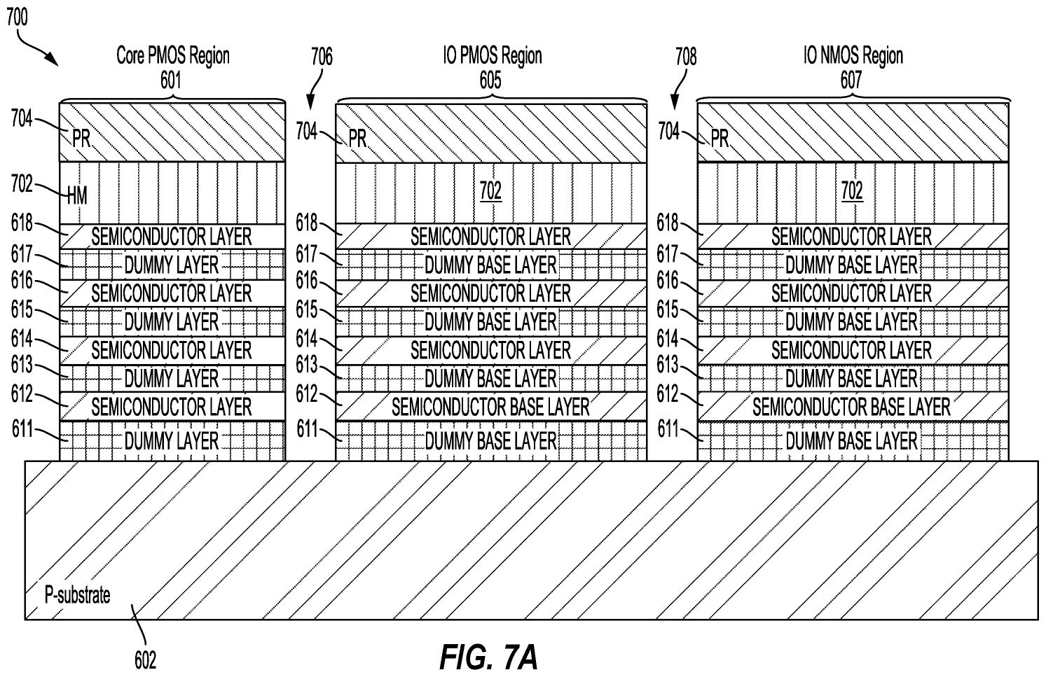

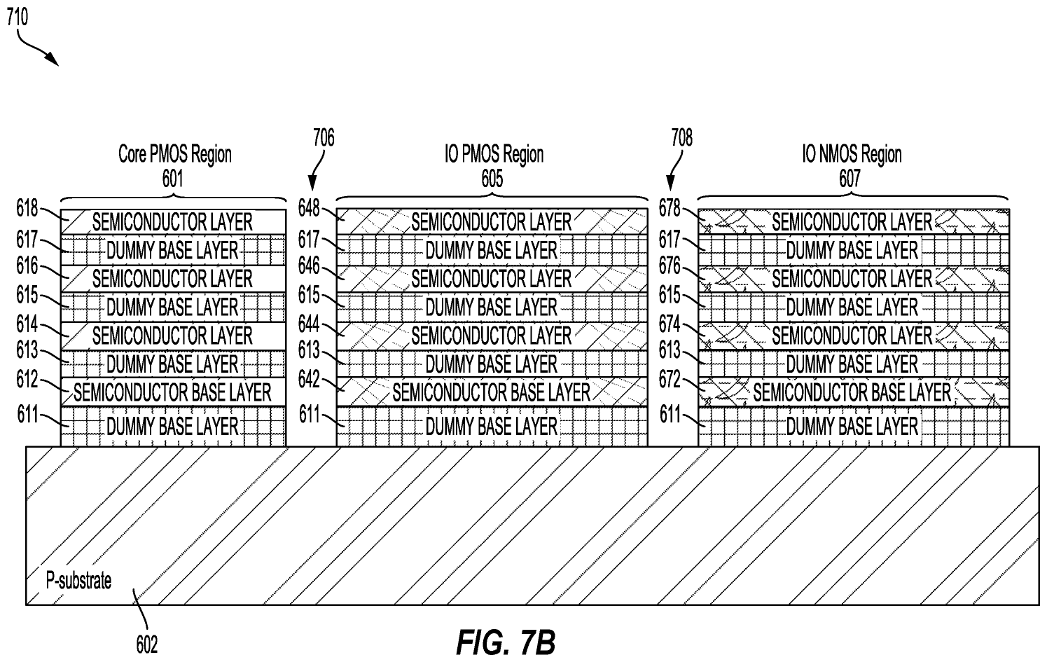

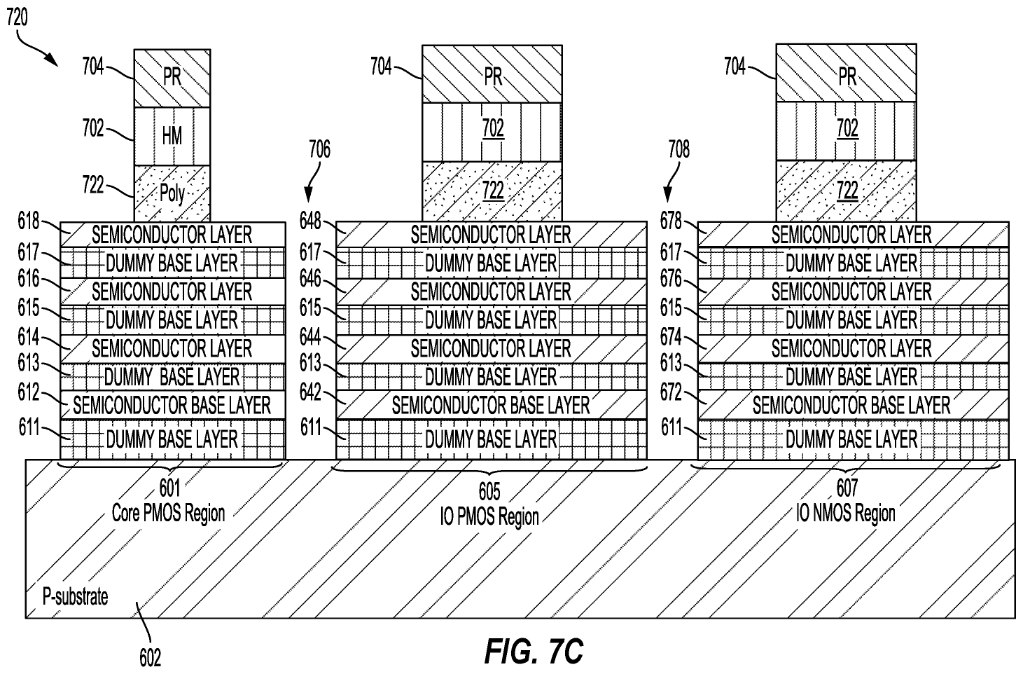

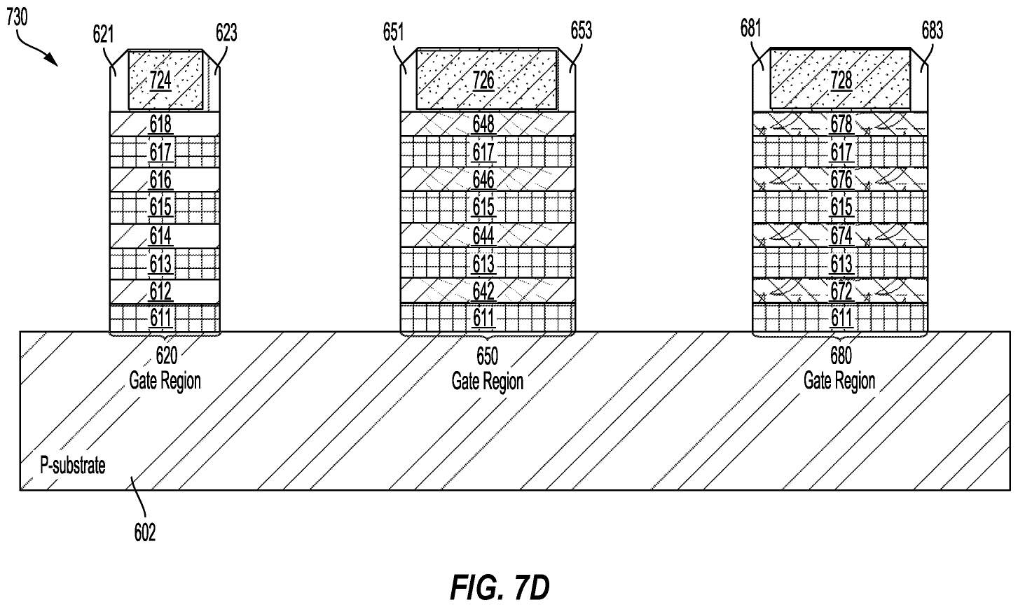

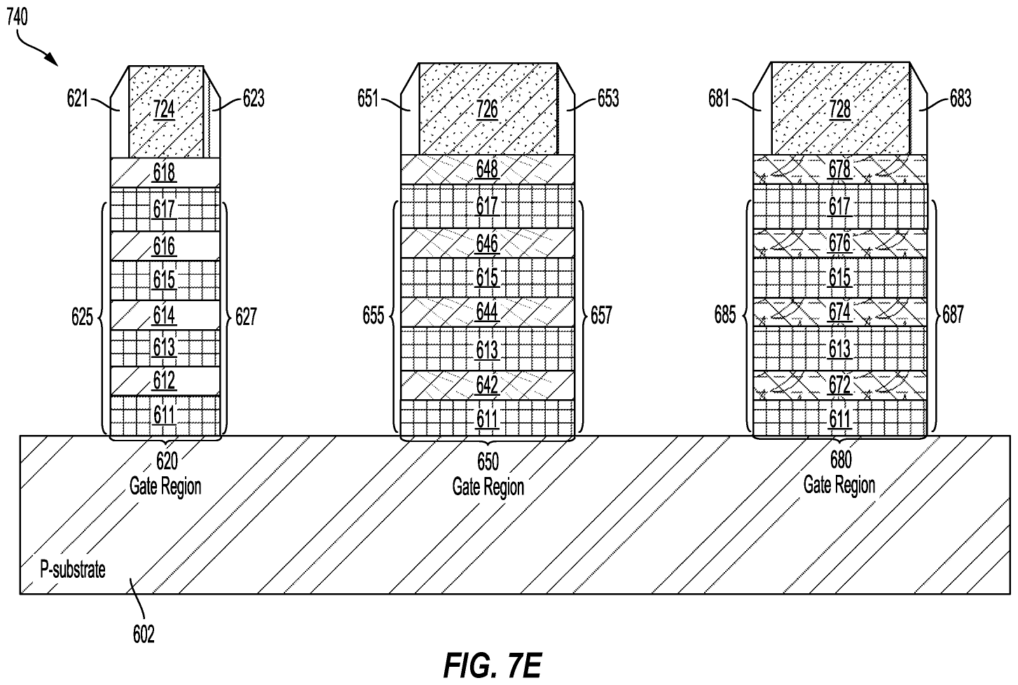

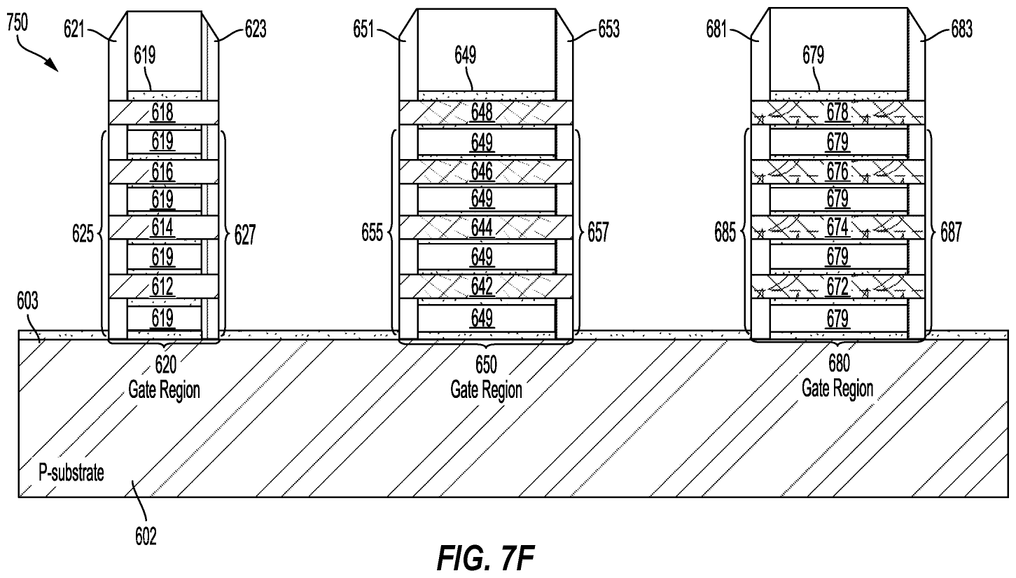

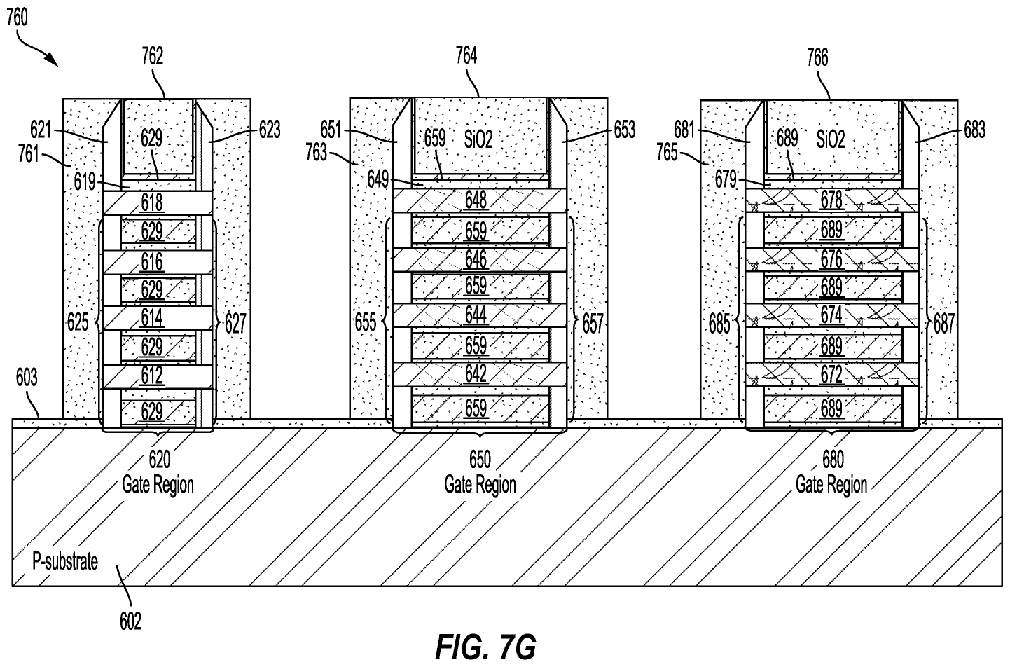

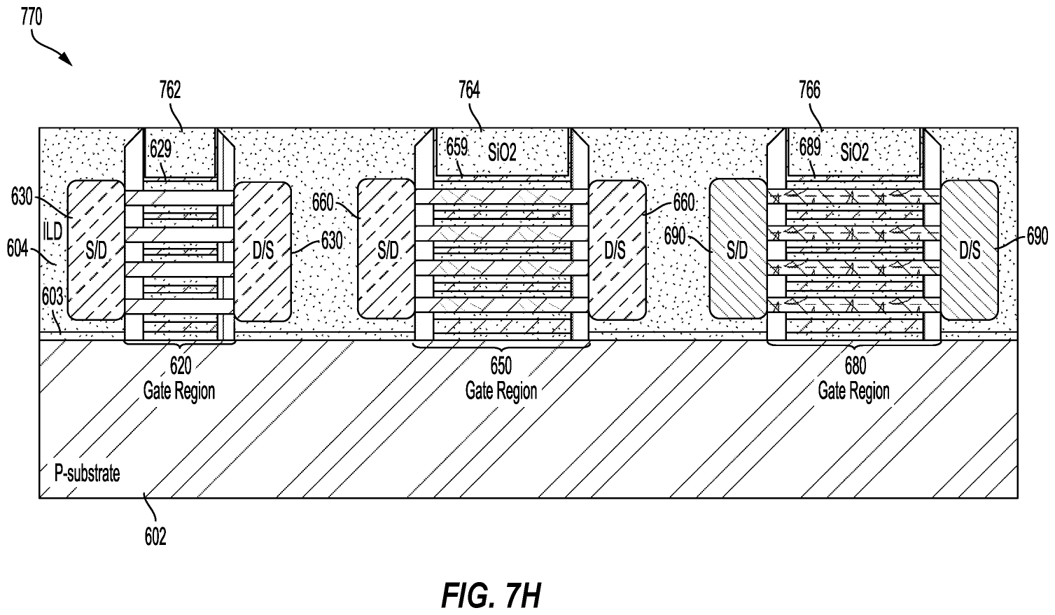

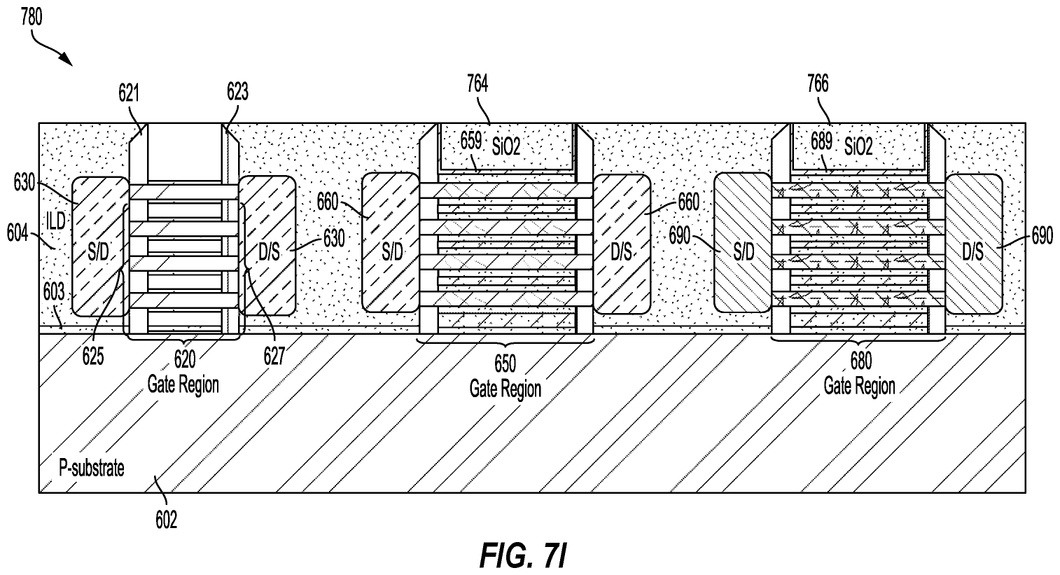

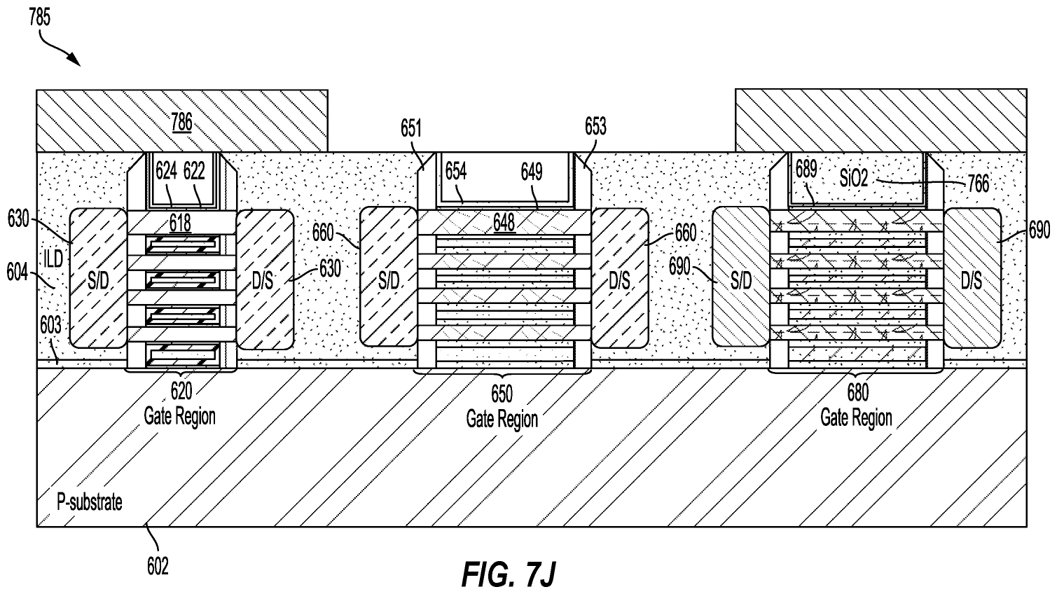

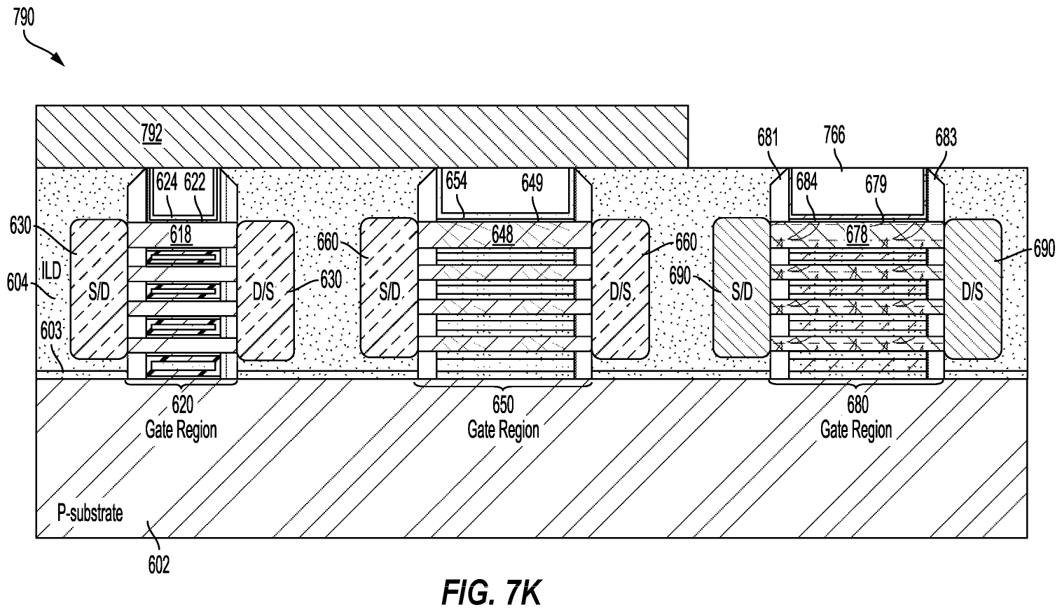

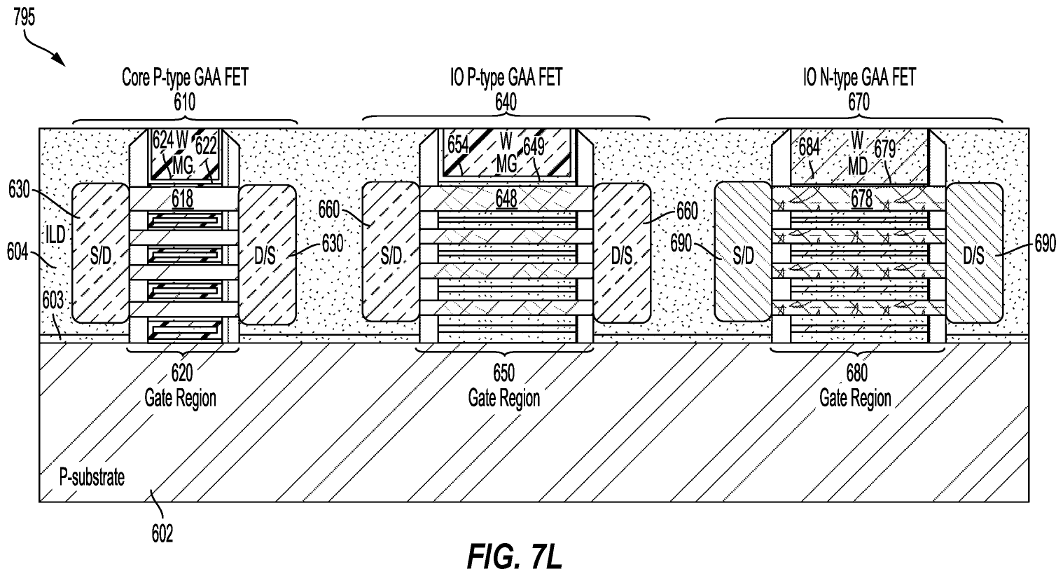

RMG technology replaces conventional polysilicon gates with a high-k (HK) metal gate (HKMG) to avoid HK dielectric crystallization incurred by conventional polysilicon gates during a thermal process. Unfortunately, a thickness of an HKMG film specified for vertical structure-based GAA FET input/output (IO) devices may limit the space available for depositing a work function metal (WFM) layer, which may be used to modulate a threshold voltage (Vₜ) of the vertical structure-based GAA FET IO device. A vertical structure-based GAA FET IO device having a metal gate and sufficient space for depositing a WFM layer is desired. According to aspects of the present disclosure, vertical structure-based GAA IO FETs having a normal-k oxide in a gate region, are described, for example, as shown in FIGS. 6 and 7A-7L.

FIG. 6 is a cross section diagram illustrating an integrated circuit (IC) device 600 including gate all around (GAA) field effect transistors (FETs) having a normal-k oxide (e.g., k˜3.8 to 4.0) in gate regions according to an input/output (IO) GAA FET configuration, according to various aspects of the present disclosure. In this example, the IC device 600 includes a core P-type GAA FET 610, an IO P-type GAA FET 640, and an IO N-type GAA FET 670 formed in an interlayer dielectric (ILD) 604 on an oxide layer 603 of a substrate 602. In various aspects of the present disclosure, an IO GAA FET configuration specifies a variation of a gate region 650 of the IO P-type GAA FET 640 and a gate region 680 of the IO N-type GAA FET 670 to provide sufficient space for depositing a work function metal.

As shown in FIG. 6, the IO P-type GAA FET 640 includes a normal-k gate oxide 649 on a semiconductor layer 648, coupled between source/drain regions 660, and a P-type work function metal (WFM) 654 on the normal-k gate oxide 649 and sidewalls of gate spacers 651, 653 and a metal gate MG coupled to the P-type WFM 654. Similarly, the IO N-type GAA FET 670 includes a normal-k gate oxide 679 on a semiconductor layer 678, coupled between source/drain regions 690, and an N-type WFM 684 on the normal-k gate oxide 679 and sidewalls of gate spacers 681, 683 and a metal gate MG coupled to the N-type WFM 684. For example, the normal-k gate oxide 640 may be a layer of silicon dioxide (SiO₂) having a thickness of five (5) to six and a half (6.5) nanometers (nm).

By contrast, the core P-type GAA FET 610 includes a high-k gate oxide 622 (e.g., k˜15 to 25) on a semiconductor layer 618, coupled between source/drain regions 630, and sidewalls of gate spacers 621, 623. Additionally, the core P-type GAA FET 610 includes a P-type WFM 624 on a base and sidewalls of the high-k gate oxide 622 and a metal gate MG coupled to the P-type work metal 624. For example, the high-k gate oxide 622 may be a layer of yttrium oxide (Y₂O₃), hafnia (HfO₂), zirconia (ZrO₂), or tantalum pentoxide (Ta₂O₅) having a thickness of two (2) to four (4) nanometers (nm). In various aspects of the present disclosure, the metal gates MG are composed of tantalum (Ta), tantalum nitride (TaN), titanium nitride (TiN), titanium (Ti), titanium aluminide (TiAl), titanium aluminide carbon (TiAl:C), tungsten (W), tungsten nitride (W:N), platinum (Pt), and/or gold (Au).

In this example, the core P-type GAA FET 610 includes metal-to-diffusion (MD) contacts to the source/drain regions 630 and metal-to-poly (MP) contacts to the metal gate MG in an ILD layer 606. The core P-type GAA FET 610 further includes zero via (V0) interconnects to the MD contacts and the metal gate MG in an ILD layer 608, and zero interconnects M0 to the zero vias V0 in an intermetal dielectric (IMD) layer 609. Additionally, the IO P-type GAA FET 640 includes MD contacts to the source/drain regions 660 and MP contacts to the metal gate MG in the ILD layer 606. The IO P-type GAA FET 640 further includes zero via V0 connects to the MD contacts in the ILD layer 608, and zero interconnects M0 to the zero vias V0 in the IMD layer 609.

Similarly, the IO N-type GAA FET 670 includes MD contacts to the source/drain regions 690 and MP contacts to the metal gate MG in the ILD layer 606. The IO N-type GAA FET 670 includes zero via V0 connects to the MD contacts in the ILD layer 608, and zero interconnects M0 to the zero vias V0 in the IMD layer 609. In various aspects of the present disclosure, the source/drain regions 690 of the IO N-type GAA FET 670 may be composed of silicon (Si), embedded silicon (eSi), germanium (Ge), gallium arsenide (GaAs), indium GaAs (InGaAs), gallium nitride (GaN), graphene, molybdenum disulfide (MoS₂), and/or phosphorus. In these aspects of the present disclosure, the source/drain regions 660 of the IO P-type GAA FET 640 and/or the source/drain regions 630 of the core P-type GAA FET 610 may be composed of silicon (Si), germanium (Ge), embedded silicon germanium (eSiGe), silicon germanium (SiGe), indium antimonide (InSb), graphene, molybdenum disulfide (MoS₂), and/or phosphorus. A process of fabricating the IC device 600 is illustrated, for example, in FIGS. 7A-7L.

FIGS. 7A-7L are schematic diagrams illustrating a process for forming the integrated circuit (IC) device 600 of FIG. 6, according to the input/out (IO) gate all around (GAA) field effect transistor (FET) configuration, according to various aspects of the present disclosure.

FIG. 7A illustrates a first step 700 in the process of forming the IC device 600 of FIG. 6 in the IO GAA FET configuration, according to some aspects of the present disclosure. At the first step 700, multiple nanosheet layers (e.g., dummy layers 611, 613, 615, and 617 and semiconductor layers 612, 614, 616, 618) are epitaxially grown (e.g., silicon (Si) germanium (SiGe)/Si layers) on the substrate 602. Once the nanosheet layers are formed, a hardmask (HM) layer 702 (e.g., silicon nitride (SiN)/oxide) and a photoresist (PR) layer 704 are deposited and formed on the nanosheet layers (e.g., dummy layers 611, 613, 615, and 617 and semiconductor layers 612, 614, 616, 618). Next, the PR layer 704 is photo patterned and the HM layer 702 is etched to form a first oxide diffusion (OD) area 706 between a core p-type metal-oxide semiconductor (PMOS) region 601 and an IO PMOS region 605. Additionally, a second OD area 708 is formed between the IO PMOS region 605 and an IO N-type metal-oxide semiconductor (NMOS) region 607.

FIG. 7B illustrates a next step 710 in the process of forming the IC device 600 of FIG. 6 in the IO GAA FET configuration, according to various aspects of the present disclosure. At step 710, the HM layer 702 and the PR layer 704 are used to separately open the first OD area 706 and the second OD area 708. Next, an N-type channel implant is performed in the nanosheet layers of the IO PMOS region 605 to form an N-type nanosheet structure. In this example, the N-channel nanosheet structure includes N-doped semiconductor layers 642, 644, 646, and 648 to provide a lightly doped N-type metal oxide semiconductor (NMOS) channel region using, for example, a phosphorus implant having a doping concentration of 10¹¹-10¹³ cm⁻³. Additionally, a P-type channel implant in performed in the nanosheet layers of the IO NMOS region 607 to form a P-type nanosheet structure. In this example, the P-type nanosheet structure includes P-doped semiconductor layers 672, 674, 676, and 678 to provide a lightly doped P-type metal oxide semiconductor (PMOS) channel region using, for example, a boron implant having a doping concentration of 10¹¹-10¹³ cm⁻³.

FIG. 7C illustrates a next step 720 in the process of forming the IC device 600 of FIG. 6 in the IO GAA FET configuration, according to various aspects of the present disclosure. At step 720, a poly layer 722 and the HM layer 702 are deposited on the core PMOS region 601, the IO PMOS region 605 and the IO NMOS region 607 of the nanosheet layers. Next, the PR layer 704 is photo patterned and the HM layer 702 and the poly layer 722 are etched to form a poly dummy gate. In this example, a dummy poly gate 724 is formed on the core PMOS region 601, a dummy poly gate 726 is formed on the IO PMOS region 605, and a dummy poly gate 728 is formed on the IO NMOS region 607 of the nanosheet layers, as shown in FIG. 7D.

FIG. 7D illustrates a next step 730 in the process of forming the IC device 600 of FIG. 6 in the IO GAA FET configuration, according to various aspects of the present disclosure. At step 730, once the dummy poly gates (724, 726, 728) are formed, ashing of the PR layer 704 and removal of the HM layer 702 are performed, followed by a cleaning process. Next, a silicon nitride space film (SiN) is deposited and etched back to form sidewall gate spacers. In this example, gate spacers 621, 623 are formed on the sidewalls of the dummy poly gate 724. Additionally, gate spacers 651, 653 are formed on the sidewalls of the dummy poly gate 726, and gate spacers 681, 683 are formed on the sidewalls of the dummy poly gate 728. The etching of the sidewall gate spacers also cuts the nanosheet layers to form a gate region 620, a gate region 650, and a gate region 680.

FIG. 7E illustrates a next step 740 in the process of forming the IC device 600 of FIG. 6 in the IO GAA FET configuration, according to various aspects of the present disclosure. At step 740, dummy layers (611, 613, 615, and 617) (e.g., silicon germanium (SiGe) layers) of the gate region 620, the gate region 650, and the gate region 680 are recessed. Once recessed, a silicon nitride (SiN) film is deposited and etched back to form inner spacers 625, 627 of the gate region 620, inner spacers 655, 657 of the gate region 650, and inner spacers 685, 687 of the gate region 680.

FIG. 7F illustrates a next step 750 in the process of forming the IC device 600 of FIG. 6 in the IO GAA FET configuration, according to various aspects of the present disclosure. At step 750, the dummy layers (611, 613, 615, and 617) of the gate region 620, the gate region 650, and the gate region 680 are removed. Additionally, the dummy poly gates (724, 726, and 728) are removed. Once removed, a gate oxide (e.g., SiO₂) is thermally grown to a predetermined thickness (e.g., approximately three (3) nanometers). In this example, the oxide layer 603 is grown on a surface of the substrate 602 and a gate oxide 619 is grown on opposing surfaces of the semiconductor layers (612, 614, 616, and 618) of the gate region 620. Similarly, a normal-k gate oxide 649 is grown on opposing surfaces of the N-doped semiconductor layers (642, 644, 646, and 648) of the gate region 650. Additionally, a normal-k gate oxide 679 is grown on opposing surfaces of the P-doped semiconductor layers (672, 674, 676, and 678) of the gate region 680.

FIG. 7G illustrates a next step 760 in the process of forming the IC device 600 of FIG. 6 in the IO GAA FET configuration, according to various aspects of the present disclosure. At step 760, a titanium nitride (TiN) layer 629 is deposited on the gate oxide 619 and on the gate spacers 621, 623 of the gate region 620. Similarly, a TiN layer 659 is deposited on the normal-k gate oxide 649 and on the gate spacers 651, 653 of the gate region 650. Additionally, a TiN layer 689 is deposited on the normal-k gate oxide 679 and on the gate spacers 681, 683 of the gate region 680. Next, an oxide (e.g., SiO₂) is deposited on the gate regions (620, 650, and 680) and etched back to form oxide layers (761, 762, 763, 764, 765, and 766).

FIG. 7H illustrates a next step 770 in the process of forming the IC device 600 of FIG. 6 in the IO GAA FET configuration, according to various aspects of the present disclosure. At step 770, the gate regions (620, 650, and 680) are separately opened and etched to remove the oxide layers (761, 763 and 765). Next, the source/drain regions 630 (e.g., embedded silicon germanium (eSiGe)) are epitaxially grown on the sidewalls of the gate region 620. Similarly, the source/drain regions 660 (e.g., eSiGe) are epitaxially grown on the sidewalls of the gate region 650. Additionally, the source/drain regions 690 (e.g., embedded silicon (eSi)) are epitaxially grown on the sidewalls of the gate region 680. Next, an oxide is deposited, and a chemical-mechanical-polish (CMP) process is performed to form the interlayer dielectric (ILD) 604.

FIG. 7I illustrates a next step 780 in the process of forming the IC device 600 of FIG. 6 in the IO GAA FET configuration, according to various aspects of the present disclosure. At step 780, the gate region 620 is opened and the gate oxide 619 and the TiN layer 629 are removed to expose the semiconductor layers (612, 614, 616, and 618). Next a high-k dielectric layer and a TiN layer are deposited on the exposed surfaces of the semiconductor layers (612, 614, 616, and 618), sidewalls of the gate spacers 621, 623, and the inner spacers 625, 627 to form the high-k gate oxide 622. Next, the P-type work function metal (WFM) 654 is deposited on the low-k gate oxide 649, as shown in FIG. 6.

FIG. 7J illustrates a next step 785 in the process of forming the IC device 600 of FIG. 6 in the IO GAA FET configuration, according to various aspects of the present disclosure. At step 785, a PR layer 786 is deposited and stripped to open the gate region 650 for removal of the TiN layers 659 and exposure of the normal-k gate oxide 649. Next, the P-type WFM 654 is deposited on the normal-k gate oxide 649 and sidewalls of the gate spacers 651, 653, as shown in FIG. 6.

FIG. 7K illustrates a step 790 in the process of forming the IC device 600 of FIG. 6 in the IO GAA FET configuration, according to various aspects of the present disclosure. At step 790, a PR layer 792 is deposited and stripped to open the gate region 680 for removal of the TiN layers 689 and exposure of the normal-k gate oxide 679. Next, the N-type WFM 684 is deposited on the normal-k gate oxide 679 and sidewalls of the gate spacers 681, 683, as shown in FIG. 6.

FIG. 7L illustrates a next step 795 in the process of forming the IC device 600 of FIG. 6 in the IO GAA FET configuration, according to various aspects of the present disclosure. At step 795, the metal gate MG is formed on the P-type WFM 624 to complete formation of the core P-type GAA FET 610 in a PMOS configuration. Similarly, the metal gate MG (e.g., tungsten (W) or cobalt (Co)) is formed on the P-type WFM 654 to complete formation of the IO P-type GAA FET 640 in a PMOS configuration. Additionally, the metal gate MG (e.g., tungsten (W)) is formed on the N-type WFM 684 to complete formation of the IO N-type GAA FET 670 in an NMOS configuration.

Referring again to FIG. 6, completing formation of the IC device 600 includes forming the MD contacts to the source/drain regions 630 of the IO P-type GAA FET 640 and MP contacts to the MG in the ILD layer 606. The core P-type GAA FET 610 further includes zero via VO interconnects (e.g., tungsten (W)) to the metal-to-diffusion (MD) contacts and the metal gate MG in the ILD layer 608, and zero interconnects M0 (e.g., copper) to the zero vias V0 in the IMD layer 609. Additionally, MD contacts to the source/drain regions 660 of the IO N-type GAA FET 670 and MP contacts to the metal gate MG in the ILD layer 606 are also formed. Similarly, forming of the zero via V0 connects to the MD contacts in the ILD layer 608, and zero interconnects M0 to the zero vias V0 in the IMD layer 609 completes the IC device 600.

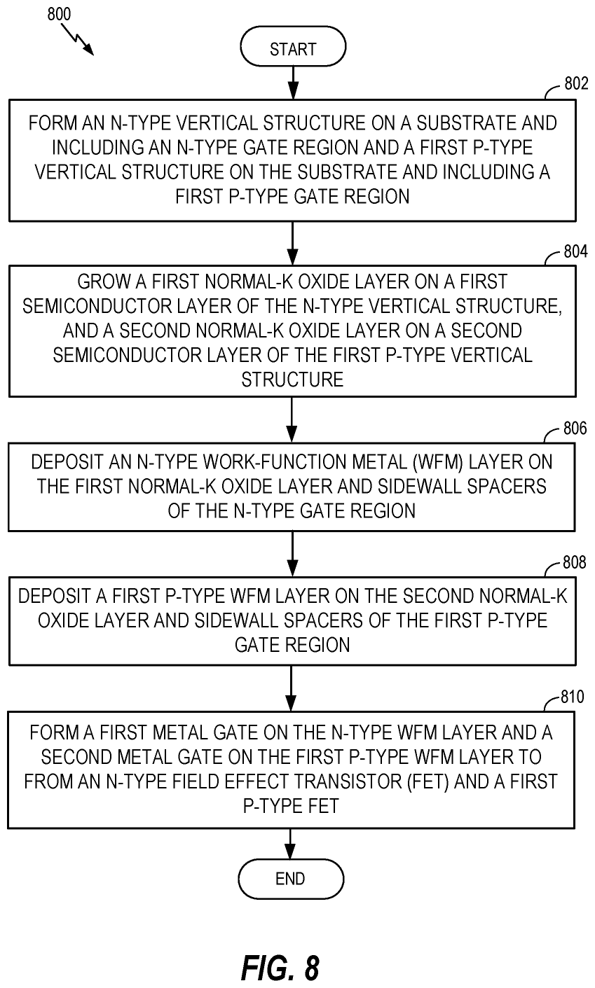

FIG. 8 is a process flow diagram illustrating a method 800 for fabricating an integrated circuit (IC) device in an input/output (IO) gate all around (GAA) field effect transistor (FET) configuration, according to various aspects of the present disclosure. The method 800 begins at block 802, in which an N-type vertical structure is formed on a substrate and including an N-type gate region and a first P-type vertical structure on the substrate and including a first P-type gate region. For example, as shown in FIG. 7D, at step 730, once the dummy poly gates (724, 726, 728) are formed, ashing of the PR layer 704 and removal of the HM layer 702 are performed, followed by a cleaning process. Next, a silicon nitride space film (SiN) is deposited and etched back to form sidewall gate spacers. In this example, gate spacers 621, 623 are formed on the sidewalls of the dummy poly gate 724. Additionally, gate spacers 651, 653 are formed on the sidewalls of the dummy poly gate 726, and gate spacers 681, 683 are formed on the sidewalls of the dummy poly gate 728. The etching of the sidewall gate spacers also cuts the nanosheet layers to form a gate region 620, a gate region 650, and a gate region 680.

At block 804, a first normal-k oxide layer is grown on a first semiconductor layer of the N-type vertical structure, and a second normal-k oxide layer is grown on a second semiconductor layer of the first P-type vertical structure. For example, as shown in FIG. 7F, a gate oxide (e.g., SiO₂) is thermally grown to a predetermined thickness (e.g., approximately three (3) nanometers). In this example, the oxide layer 603 is grown on a surface of the substrate 602 and a gate oxide 619 is grown on opposing surfaces of the semiconductor layers (612, 614, 616, and 618) of the gate region 620. Similarly, a normal-k gate oxide 649 is grown on opposing surfaces of the N-doped semiconductor layers (642, 644, 646, and 648) of the gate region 650. Additionally, a normal-k gate oxide 679 is grown on opposing surfaces of the P-doped semiconductor layers (672, 674, 676, and 678) of the gate region 680.

At block 806, an N-type work-function metal (WFM) layer is deposited on the first normal-k oxide layer and sidewall spacers of the N-type gate region. For example, as shown in FIG. 7K, at step 790, a PR layer 792 is deposited and stripped to open the gate region 680 for removal of the TiN layers 689 and exposure of the normal-k gate oxide 679. Next, the N-type WFM 684 is deposited on the normal-k gate oxide 679 and sidewalls of the gate spacers 681, 683, as shown in FIG. 6.

At block 808, a first P-type WFM layer is deposited on the second normal-k oxide layer and sidewall spacers of the first P-type gate region. For example, as shown in FIG. 7J, at step 785, a PR layer 786 is deposited and stripped to open the gate region 650 for removal of the TiN layers 659 and exposure of the normal-k gate oxide 649. Next, the P-type WFM 654 is deposited on the normal-k gate oxide 649 and sidewalls of the gate spacers 651, 653, as shown in FIG. 6.

At block 810, a first metal gate is formed on the N-type WFM layer, and a second metal gate is formed on the first P-type WFM layer to from an N-type field effect transistor (FET) and a first P-type FET. For example, as shown in FIG. 7L, at step 795, the metal gate MG is formed on the P-type WFM 624 to complete formation of the core P-type GAA FET 610 in a PMOS configuration. Similarly, the metal gate MG (e.g., tungsten (W) or cobalt (Co)) is formed on the P-type WFM 654 to complete formation of the IO P-type GAA FET 640 in a PMOS configuration. Additionally, the metal gate MG (e.g., tungsten (W)) is formed on the N-type WFM 684 to complete formation of the IO N-type GAA FET 670 in an NMOS configuration.

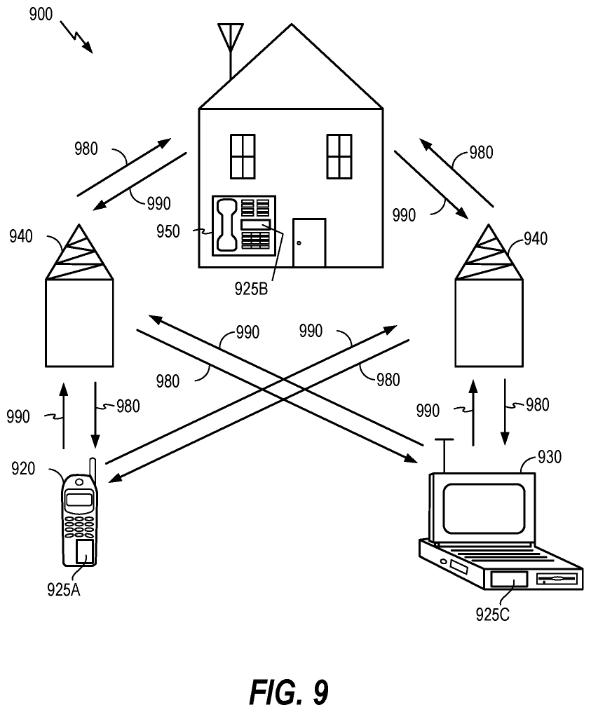

FIG. 9 is a block diagram showing an exemplary wireless communications system 900 in which an aspect of the disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include IC devices 925A, 925C, and 925B that include the disclosed GAA FETs. It will be recognized that other devices may also include the disclosed GAA FETs, such as the base stations, switching devices, and network equipment. FIG. 9 shows forward link signals 980 from the base station 940 to the remote units 920, 930, and 950, and reverse link signals 990 from the remote units 920, 930, and 950 to base station 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed GAA FETs.

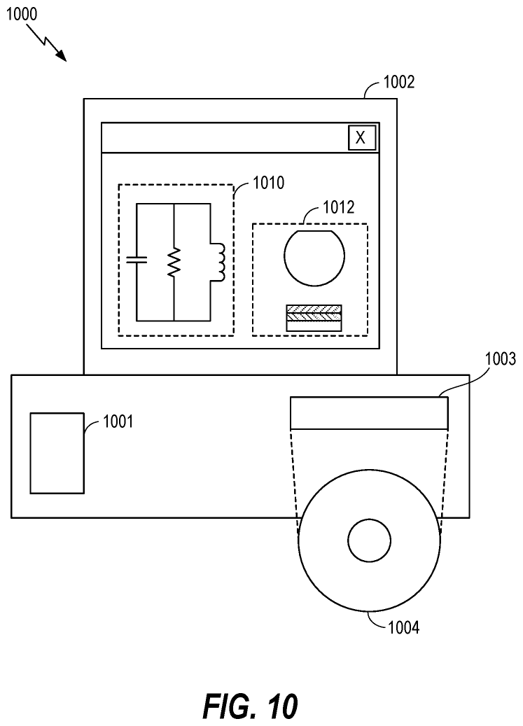

FIG. 10 is a block diagram illustrating a design workstation used for circuit, layout, and logic design of an IC structure, such as the FinFET disclosed above. A design workstation 1000 includes a hard disk 1001 containing operating system software, support files, and design software such as Cadence or OrCAD. The design workstation 1000 also includes a display 1002 to facilitate design of a circuit 1010 or a nanosheet structure 1012 including a GAA FET. A storage medium 1004 is provided for tangibly storing the design of the circuit 1010 or the nanosheet structure 1012. The design of the circuit 1010 or the nanosheet structure 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the nanosheet structure 1012 by decreasing the number of processes for designing semiconductor wafers.

Implementation examples are described in the following numbered clauses:
1. An integrated circuit (IC) device, comprising:
a substrate;
an N-type field effect transistor (FET) comprising an N-type vertical structure on the substrate and including an N-type gate region having a first normal-k oxide layer on a semiconductor layer of the N-type vertical structure, an N-type work-function metal (WFM) layer on the first normal-k oxide layer and sidewall spacers of the N-type gate region, and a first metal gate on the N-type WFM layer; and
a first P-type FET, comprising a first P-type vertical structure on the substrate and including a first P-type gate region having a second normal-k oxide layer on a first semiconductor layer of the first P-type vertical structure, a first P-type WFM layer on the second normal-k oxide layer and sidewall spacers of the first P-type gate region, and a second metal gate on the first P-type WFM layer.
2. The IC device of clause 1, in which the N-type vertical structure comprises a P-type nanosheet structure.
3. The IC device of any of clauses 1 or 2, in which the first P-type vertical structure comprises an N-type nanosheet structure.
4. The IC device of any of clauses 1-3, further comprising a second P-type FET, comprising a second P-type vertical structure on the substrate, and including a second P-type gate region having a high-k gate oxide layer on a second semiconductor layer of the second P-type vertical structure and sidewall spacers of the second P-type gate region.
5. The IC device of clause 4, in which the second P-type FET further comprises a second P-type WFM layer on the high-k gate oxide layer, and a third metal gate on the second P-type WFM layer.
6. The IC device of any of clauses 4 or 5, in which the high-k gate oxide layer is on a surface of the substrate.
7. The IC device of any of clauses 1-6, in which the first normal-k oxide layer and the second normal-k oxide layer are on a surface of the substrate.
8. The IC device of any of clauses 1-7, in which the N-type vertical structure comprises a lightly doped P-type channel region between a source/drain region and a drain/source region.
9. The IC device of any of clauses 1-8, in which the first P-type vertical structure comprises a lightly doped N-type channel region between a source/drain region and a drain/source region.
10. The IC device of any of clauses 1-9, further comprising an input/output (IO) pad coupled to at least one of a source/drain region of the N-type FET and a drain/source region of the first P-type FET.
11. A method for fabricating an integrated circuit device, comprising:
forming an N-type vertical structure on a substrate and including an N-type gate region and a first P-type vertical structure on the substrate and including a first P-type gate region;
growing a first normal-k oxide layer on a first semiconductor layer of the N-type vertical structure, and a second normal-k oxide layer on a second semiconductor layer of the first P-type vertical structure;
depositing an N-type work-function metal (WFM) layer on the first normal-k oxide layer and sidewall spacers of the N-type gate region;
depositing a first P-type WFM layer on the second normal-k oxide layer and sidewall spacers of the first P-type gate region; and
forming a first metal gate on the N-type WFM layer and a second metal gate on the first P-type WFM layer to from an N-type field effect transistor (FET) and a first P-type FET.
12. The method of clause 11, in which the N-type vertical structure comprises a P-type nanosheet structure.
13. The method of any of clauses 11 or 12, in which the first P-type vertical structure comprises an N-type nanosheet structure.
14. The method of any of clauses 11-13, further comprising forming a second P-type FET, comprising a second P-type vertical structure on the substrate, and including a second P-type gate region having a high-k gate oxide layer on the second semiconductor layer of the second P-type vertical structure and sidewall spacers of the second P-type gate region.
15. The method of clause 14, in which the second P-type FET further comprises a second P-type WFM layer on the high-k gate oxide layer, and a third metal gate on the second P-type WFM layer.
16. The method of any of clauses 14 or 15, in which the high-k gate oxide layer is on a surface of the substrate.
17. The method of any of clauses 11-16, in which the first normal-k oxide layer and the second normal-k oxide layer are on a surface of the substrate.
18. The method of any of clauses 11-17, in which the N-type vertical structure comprises a lightly doped P-type channel region between a source/drain region and a drain/source region.
19. The method of any of clauses 11-18, in which the first P-type vertical structure comprises a lightly doped N-type channel region between a source/drain region and a drain/source region.
20. The method of any of clauses 11-19, further comprising forming an input/output (IO) pad coupled to at least one of a source/drain region of the N-type FET and a drain/source region of the first P-type FET.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor. or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC) device, comprising:
a substrate;
an N-type field effect transistor (FET) comprising an N-type vertical structure on the substrate and including an N-type gate region having a first normal-k oxide layer on a semiconductor layer of the N-type vertical structure, an N-type work-function metal (WFM) layer on the first normal-k oxide layer and sidewall spacers of the N-type gate region, and a first metal gate on the N-type WFM layer; and
a first P-type FET, comprising a first P-type vertical structure on the substrate and including a first P-type gate region having a second normal-k oxide layer on a first semiconductor layer of the first P-type vertical structure, a first P-type WFM layer on the second normal-k oxide layer and sidewall spacers of the first P-type gate region, and a second metal gate on the first P-type WFM layer.

2. The IC device of claim 1, in which the N-type vertical structure comprises a P-type nanosheet structure.

3. The IC device of claim 1, in which the first P-type vertical structure comprises an N-type nanosheet structure.

4. The IC device of claim 1, further comprising a second P-type FET, comprising a second P-type vertical structure on the substrate, and including a second P-type gate region having a high-k gate oxide layer on a second semiconductor layer of the second P-type vertical structure and sidewall spacers of the second P-type gate region.

5. The IC device of claim 4, in which the second P-type FET further comprises a second P-type WFM layer on the high-k gate oxide layer, and a third metal gate on the second P-type WFM layer.

6. The IC device of claim 4, in which the high-k gate oxide layer is on a surface of the substrate.

7. The IC device of claim 1, in which the first normal-k oxide layer and the second normal-k oxide layer are on a surface of the substrate.

8. The IC device of claim 1, in which the N-type vertical structure comprises a lightly doped P-type channel region between a source/drain region and a drain/source region.

9. The IC device of claim 1, in which the first P-type vertical structure comprises a lightly doped N-type channel region between a source/drain region and a drain/source region.

10. The IC device of claim 1, further comprising an input/output (IO) pad coupled to at least one of a source/drain region of the N-type FET and a drain/source region of the first P-type FET.

11. A method for fabricating an integrated circuit device, comprising:
forming an N-type vertical structure on a substrate and including an N-type gate region and a first P-type vertical structure on the substrate and including a first P-type gate region;
growing a first normal-k oxide layer on a first semiconductor layer of the N-type vertical structure, and a second normal-k oxide layer on a second semiconductor layer of the first P-type vertical structure;
depositing an N-type work-function metal (WFM) layer on the first normal-k oxide layer and sidewall spacers of the N-type gate region;
depositing a first P-type WFM layer on the second normal-k oxide layer and sidewall spacers of the first P-type gate region; and
forming a first metal gate on the N-type WFM layer and a second metal gate on the first P-type WFM layer to from an N-type field effect transistor (FET) and a first P-type FET.

12. The method of claim 11, in which the N-type vertical structure comprises a P-type nanosheet structure.

13. The method of claim 11, in which the first P-type vertical structure comprises an N-type nanosheet structure.

14. The method of claim 11, further comprising forming a second P-type FET, comprising a second P-type vertical structure on the substrate, and including a second P-type gate region having a high-k gate oxide layer on a third semiconductor layer of the second P-type vertical structure and sidewall spacers of the second P-type gate region.

15. The method of claim 14, in which the second P-type FET further comprises a second P-type WFM layer on the high-k gate oxide layer, and a third metal gate on the second P-type WFM layer.

16. The method of claim 14, in which the high-k gate oxide layer is on a surface of the substrate.

17. The method of claim 11, in which the first normal-k oxide layer and the second normal-k oxide layer are on a surface of the substrate.

18. The method of claim 11, in which the N-type vertical structure comprises a lightly doped P-type channel region between a source/drain region and a drain/source region.

19. The method of claim 11, in which the first P-type vertical structure comprises a lightly doped N-type channel region between a source/drain region and a drain/source region.

20. The method of claim 11, further comprising forming an input/output (IO) pad coupled to at least one of a source/drain region of the N-type FET and a drain/source region of the first P-type FET.
